(19) United States
(12) Patent Application Publication
(10) Pub. No.: US 2003/0025446 A1
(43) Pub. Date: Feb. 6, 2003

(54) Manufacturing method and structure of OLED display panel

(76) Inventors: Hung-Yi Lin, Hsinchu City (TW); Tung-Chuan Wu, Hsinchu City (TW); Bao-Hong Chen, Kaohsiung Hsien (TW)

Correspondence Address: BIRCH STEWART KOLASCH & BIRCH, PO BOX 747, FALLS CHURCH, VA, 22040-0747, US

(21) Appl. No.: 09/917,684

(22) Filed: Jul. 31, 2001

(51) Int. Cl. H01J 1/62

(52) U.S. Cl. 313/504

(57) ABSTRACT

The present invention relates to a manufacturing method and a structure of organic light-emitting diode display panels. By precisely controlling the position—shape and thickness of the organic light-emitting layer of pixels, the conventional cross talk problem can be solved and a better quality and longer lifetime for the OLED can be obtained. This method is to form a plurality of long grooves on a substrate, then fill the grooves with a conducting material to form a plurality of first electrode lines. A cavity matrix is formed on the first electrodes. Each individual cavity of the cavity matrix corresponds to a pixel. An organic light-emitting layer is filled in the cavities. Repeat the above steps three times, and a red-green-blue three-color organic light-emitting matrix can be obtained. A plurality of second electrode lines are formed on the organic light-emitting layer. The second electrode lines are horizontally parallel for connecting the organic light-emitting layer with the same horizontal position. Hence, a full-color organic light-emitting diode display panel can be obtained.

### BACKGROUND OF THE INVENTION

1. Field of Invention

The invention relates to a manufacturing method and structure of organic light-emitting diode (OLED) display panels, and especially for organic light-emitting diode display panels having a 3-dimensional structure.

2. Related Art

As electronic products are becoming lighter and smaller, various kinds of planar displayers have begun to be substituted for traditional cathode ray tube (CRT) displayers, and have been applied to many display devices of different fields. The planar displayer is an important communication interface between human and machine when considering various kinds of portable communication and information products. The OLED displayer is a planar displayer with advantages such as low activation voltage , high responding speed—low power consumption—no view angle limitation—full colors—wide application and suitable operation temperature. The OLED has been an important part of the research of big enterprises and institutes in recent years. The OLED uses an organic light-emitting diode as a light source for each individual pixel on the displayer. The advantage of low power consumption can be achieved because the OLED requires low activation power and small light-emitting current. The fundamental structure of the OLED is as shown in FIG. 1. It is comprised of an anode 2, and as an example, an indium tin oxide (ITO) transparent electrode film is coated on a glass substrate 1 (or transparent plastic substrate) by sputtering or vapor deposition process. An organic light-emitting layer 3 and a cathode 4 are sequentially formed on the anode 2. The light-emitting theory of the OLED holds that holes and electrons are introduced into the organic light-emitting layer 3 between two electrodes by a driving force generated from the anode 2 and cathode 4. The organic light-emitting layer 3 can be more than one layer of organic thin-film. For example, the organic light-emitting layer 3 can contain a hole injection layer (HIL)—hole transport layer (HTL)—light-emitting layer (EL) and electron transport layer (ETL). In addition to those layers mentioned above, the organic light-emitting layer 3 can also include other kinds of films when special functions are taken into consideration. The convention manufacturing method of the OLED display panel is to form an indium tin oxide (ITO) layer on a transparent substrate by a sputtering process or by vapor deposition. Many layers of organic material are formed on the indium tin oxide by the combination of a metal mask process—photolithography process and etching process. Then a metal electrode is formed by vapor deposition process. The OLED display panel produced by this kind of 2-dimensional process is, for example, the passive matrix organic light-emitting diode (PMOLED). Several drawbacks of the conventional process are inevitably present, such as the difficulty of controlling the thickness of the organic material of the pixels, the fact that the light magnitude of each pixel is not uniform, the ease of running into a cross talk problem because of current leakage, and the complications stemming from the necessity of numerous mask alignment and photolithographic processes.

Therefore, a novel manufacturing method and structure of the OLED display panel is proposed in the invention to overcome these above mentioned problems of the conventional process.

### SUMMARY OF THE INVENTION

An object of the invention is to propose a novel manufacturing method and structure of the OLED display panel to overcome the cross talk problem occurring in conventional passive matrix organic light-emitting diode display panels, and to simplify the manufacturing process.

A second object of the invention is to propose a novel manufacturing method and structure of the OLED display panel to precisely control the position—shape and thickness of the organic light-emitting layer of pixels to obtain the best possible display quality.

A third object of the invention is to propose a novel manufacturing method and structure of the OLED display panel to reduce the problems occurring in the subsequent packaging process. The yield and lifetime of the OLED display panel is increased accordingly.

In order to obtain the objects mentioned above, a 3-dimensional cavity structure is formed on a substrate (a glass substrate or transparent plastic substrate). For example, a plurality of long grooves parallel to each other are formed on the substrate with an excimer laser, then the grooves are filled by a conducting material (for example, indium tin oxide) to form a plurality of first electrode lines. A cavity matrix is then formed on the first electrodes with an excimer laser. Each individual cavity of the cavity matrix corresponds to a pixel. A three-dimensional cavity structure is thus produced. Subsequently, an organic light-emitting layer is filled in the cavities. When the cavities are being formed, the position—shape and depth of the cavities is precisely controlled so the position—shape and thickness of the organic light-emitting layer of pixels can thus be precisely controlled to create the best conditions for the display panel. By using this method, the organic light-emitting layer of each pixel can be separated and the cross talk problems of the PMOLED display panel can be avoided. Moreover, the organic light-emitting layer is embedded in the cavity after the packaging process, so problems resulting from bad packaging can be avoided. In other words, the organic light-emitting layer will not decay easily. The yield and lifetime of the display panel is increased.

The invention proposes a manufacturing method of a full color OLED display panel, wherein a red-green-blue three-color organic light-emitting matrix is formed on a substrate. The process is comprised of the following steps: form a plurality of grooves on the substrate, which are vertically parallel; form a plurality of first electrode lines in the grooves; form a cavity matrix on the first electrode lines; fill an organic light-emitting layer in the cavities of the cavity matrix to form an organic light-emitting matrix; repeat the above steps three times to form a red-green-blue three-color organic light-emitting matrix; and form a plurality of second electrode lines on the substrate and the organic light-emitting layer, the second electrode lines are horizontally parallel for connecting the said organic light-emitting layers with the same horizontal position.

These processes for forming a plurality of grooves and the cavity matrix are done with an excimer laser. The first electrode lines can be indium tin oxide. The first electrode lines can be obtained by forming a layer of indium tin oxide on the substrate by sputtering or deposition process, then polished by a chemical mechanical polishing process. The organic light-emitting layer can comply with more than one layer of organic material thin film. The organic light-emitting layer can be obtained by forming organic material in the cavities through an inkjet printing or thermal evaporating process. Then use a chemical mechanical process to form an organic light-emitting layer in the cavities. This novel process doesn't require numerous mask alignment or photolithographic processes, so the manufacturing process is greatly simplified.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given herein below. However, this description is for purposes of illustration only, and thus is not limitative of the invention, wherein:

FIG. 1 illustrates cross-sectional view of the conventional structure of the OLED.

FIGS. 2A˜2G illustrate manufacturing processes of the OLED display panel of the invention.

FIG. 2A illustrates a substrate.

FIG. 2B illustrates a plurality of grooves formed on the substrate.

FIG. 2C illustrates a plurality of first electrode lines formed in a plurality of grooves.

FIG. 2D illustrates the substrate and cross-section view in the A-A′ direction, and a cavity matrix formed on the substrate.

FIG. 2E illustrates an organic light-emitting layer formed on each cavity of the cavity matrix.

FIG. 2F illustrates a three-color organic light-emitting matrix formed on the substrate.

FIG. 2G illustrates a plurality of second electrode lines formed on the organic light-emitting layer for connecting the organic light-emitting layers with the same horizontal position.

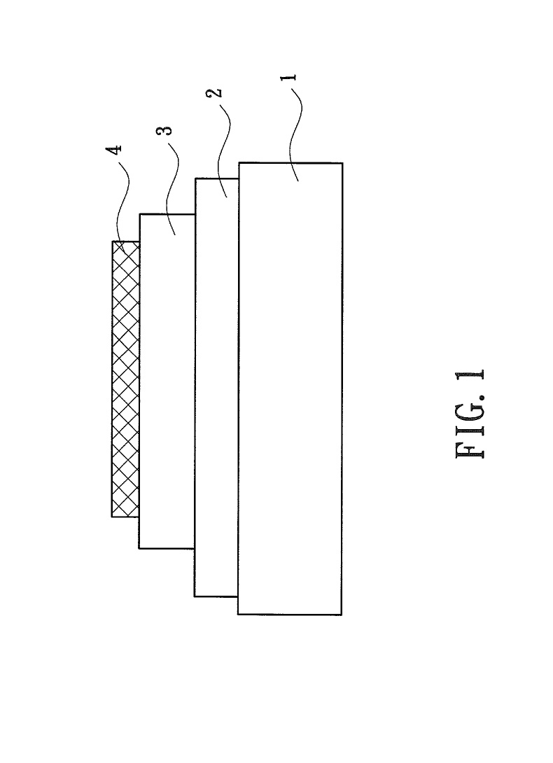

### DETAILED DESCRIPTION OF THE INVENTION

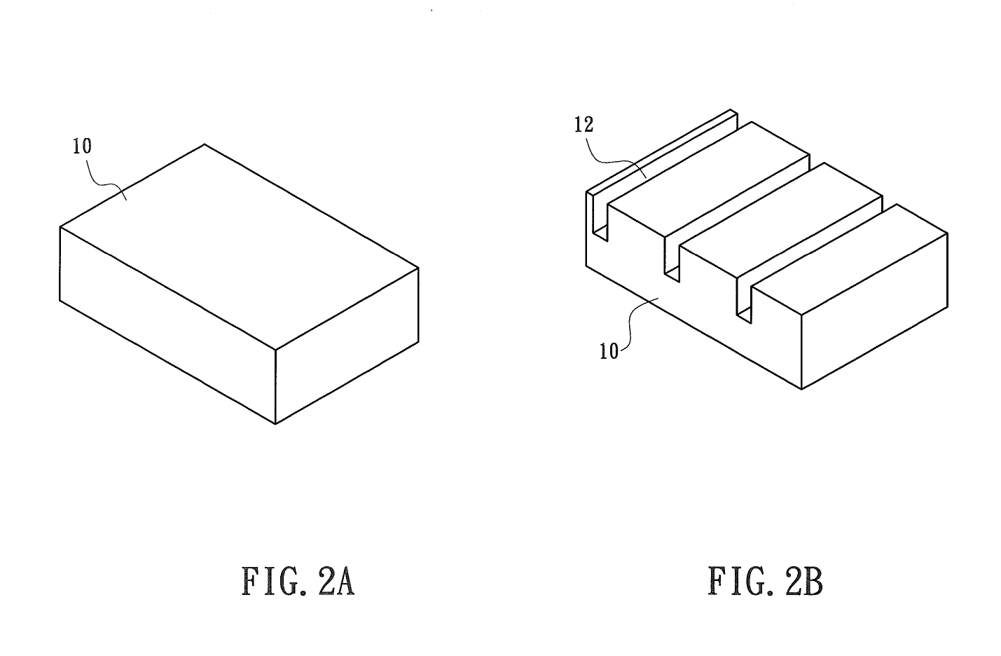

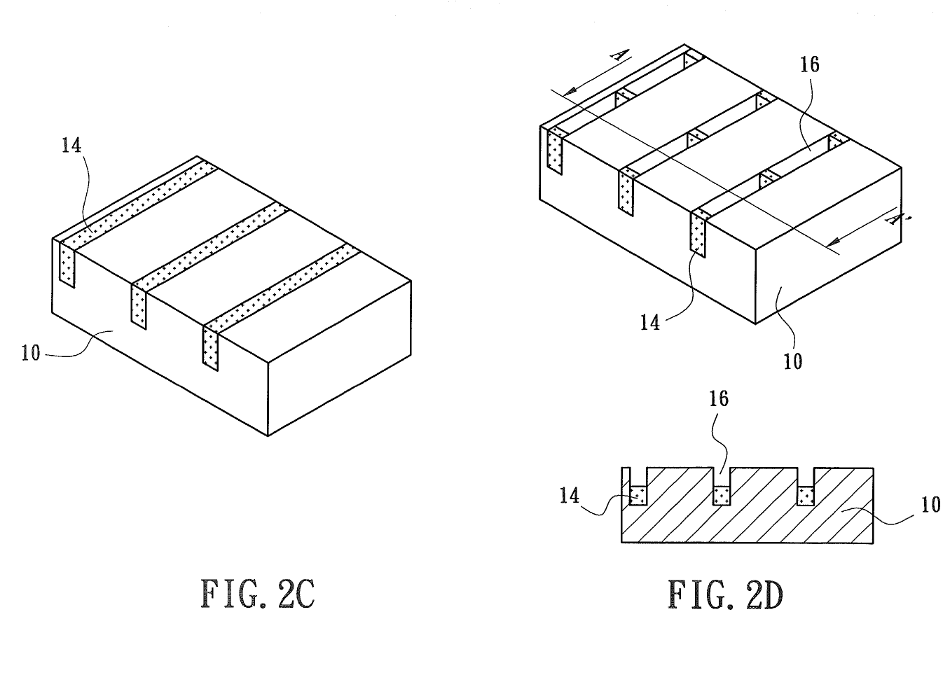

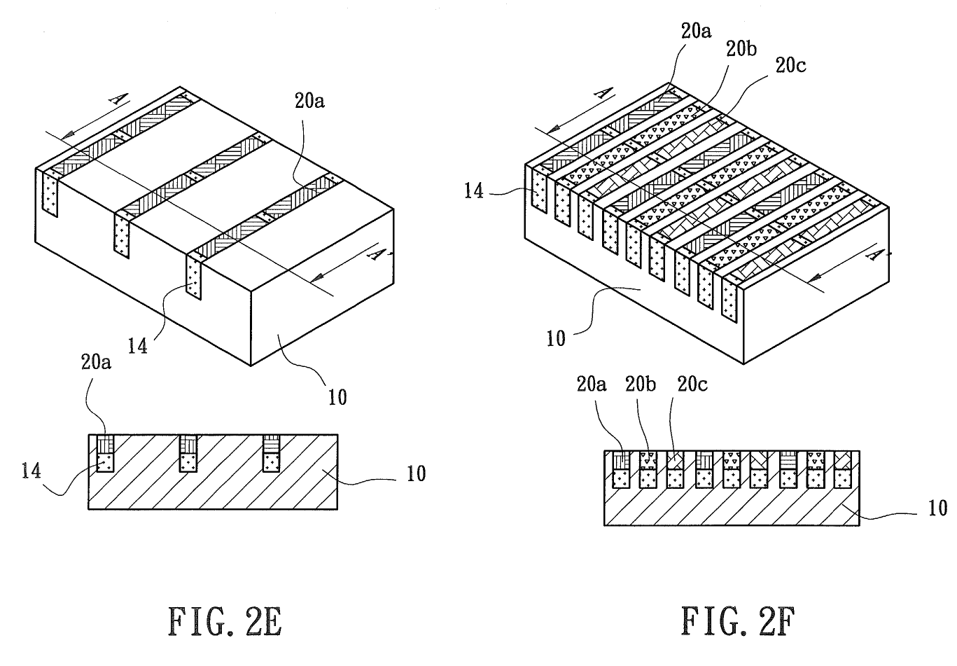

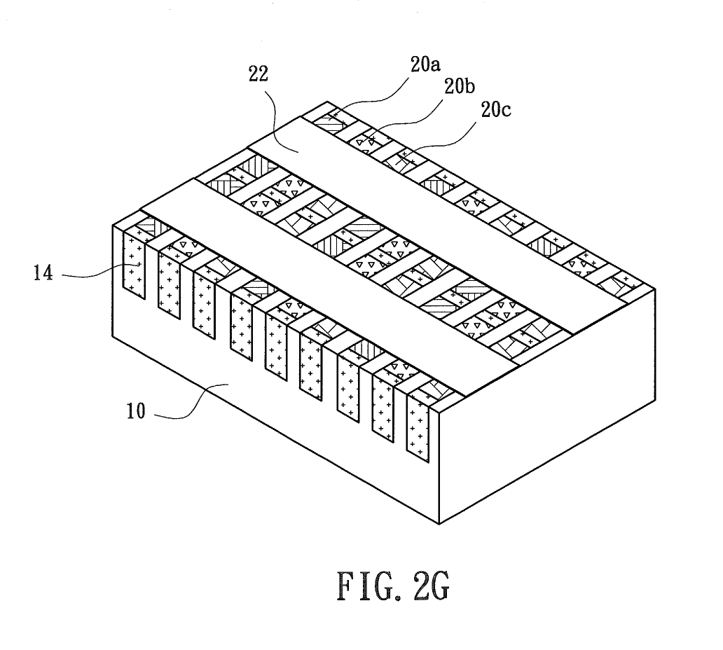

FIGS. 2A˜2G illustrate manufacturing processes of the full color OLED display panel of the invention. The full-color OLED display panel contains a light-emitting array of red, green, and blue.

FIG. 2A illustrates a substrate 10, preferably a transparent glass substrate or a transparent plastic substrate. Referring to FIG. 2B, a plurality of grooves 12 are formed on the substrate 10. These grooves are vertically parallel and the spacing between two neighboring grooves is fixed. The depth of the cavity 12 is, for example, 3000 Å. An excimer laser can be used to form the grooves 12.

As shown in FIG. 2C, indium tin oxide (ITO) transparent conducting material is filled in the grooves 12 to form a plurality of ITO electrode lines 14. A better method of forming ITO transparent conducting material is to form an ITO thin film on the substrate 10 and fill the grooves 12 by sputtering or vapor deposition process, then remove the spare ITO thin film that is on the substrate 10 and beyond the top of the groove. After that, ITO electrode lines 14 are formed in the grooves 12.

As shown in FIG. 2D, a cavity matrix is formed on the ITO electrode lines 14. The cavity matrix contains a plurality of cavities 16 of the same size. The cavities are uniformly arranged on the ITO electrode lines 14. The cavity matrix is formed by partially removing the surface of the ITO electrode lines 14 with an excimer laser. Because of the high precision of the excimer laser, the position, shape and depth of the cavities can be precisely controlled to create the best conditions during the forming of the cavities 16. The depth of the cavities 16 is, for example, about 1500 Å.

Referring to FIG. 2E, an organic light-emitting layer 20a (for example, a red light organic light-emitting layer) can be deposited into each cavity 16 by an inkjet printing process. The organic light-emitting layer 20 is not limited to only one thin film. According to the requirements of different products, the organic light-emitting layer 20 can contain several layers of organic thin film. For example, the organic thin film can be a hole injection layer (HIL)—hole transport layer (HTL)—light-emitting layer (EL) and electron transport layer (ETL). In the invention, it is also possible to utilize a thermal evaporation process together with a chemical mechanical polishing process to form the organic light-emitting layer 20a in the cavities 16. The method is to form an organic light-emitting layer 20a on the substrate 10 and the cavities 16, and remove the extra part of the organic light-emitting layer that is on the substrate and above the top of the cavities. A red light organic light-emitting matrix is formed accordingly.

Referring to FIG. 2F, by repeating the steps mentioned above, those who are familiar with the conventional process of the OLED are able to form a green light organic light-emitting layer 20b for the green light organic light-emitting matrix, and a blue light organic light-emitting layer 20c for the blue light organic light-emitting matrix.

As shown in FIG. 2G, a plurality of metal electrode lines 22 are formed on the substrate 10 and the organic light-emitting layers 20a—20b—and 20c. These metal electrode lines 22 are horizontally parallel for the connection of the organic light-emitting layers 20a˜20b—and 20c.

By using the manufacturing method of the invention, the organic light-emitting layer of each pixel can be separated and the cross talk problem of the PMOLED display panel can be avoided. Traditionally complicated methods requiring numerous mask processes are thus simplified. By precisely controlling the position—shape and thickness of the cavities, a precise position—shape and thickness of the organic light-emitting layer of pixels can be achieved. A high quality display panel is thus obtained. Moreover, the organic light-emitting layer is embedded in the cavity after the packaging process, so problems resulting from bad packaging can be avoided. Improved packaging quality gives rise to better quality and longer lifetime for the OLED.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of making an OLED display panel, wherein a light-emitting display array is formed on a substrate comprising:
forming a plurality of grooves on said substrate, said grooves are parallel to a vertical direction;
forming a plurality of first electrode lines in said grooves;
forming a cavity matrix on said first electrode lines;
filling an organic light-emitting layer in the cavities of said cavity matrix to form an organic light-emitting matrix; and
forming a plurality of second electrode lines on said substrate and said organic light-emitting layer, said second electrode lines are parallel to a horizontal direction for connecting said organic light-emitting layer with the same horizontal position.

2. The method of claim 1, wherein said first electrode lines are made of indium tin oxide film and said second electrode lines are made of metal thin film.

3. The method of claim 1, wherein said grooves and said cavity matrix are formed using excimer laser.

4. The method of claim 1, wherein the step of forming a first electrode lines in said grooves comprises:
depositing an indium tin oxide thin film on said substrate, whereby said grooves are filled by said indium tin oxide thin film; and
removing extra part of said indium tin oxide thin film which is on said substrate surface and beyond the top of said grooves with chemical mechanical polishing.

5. The method of claim 1, wherein said organic light-emitting layer is form in every said cavity by inkjet printing.

6. The method of claim 1, wherein the step of filling an organic light-emitting layer in the cavities of said cavity matrix to form an organic light-emitting matrix comprises;
forming an organic light-emitting layer on said substrate using thermal evaporation, whereby said cavities are filled with said organic light-emitting layer; and
removing extra part of said organic light-emitting layer which is on said substrate surface and beyond the top of said cavities using chemical mechanical polishing.

7. A method of making an OLED display panel, wherein a full color light-emitting display array is formed on a substrate comprising:
forming a plurality of grooves on said substrate, said grooves are parallel to a vertical direction;
forming a plurality of first electrode lines in said grooves;
forming a cavity matrix on said first electrode lines;
filling an organic light-emitting layer in the cavities of said cavity matrix to form an organic light-emitting matrix;
repeating above steps three times to form red-green-blue three-color organic light-emitting matrix; and
forming a plurality of second electrode lines on said substrate and said organic light-emitting layer, said second electrode lines are parallel to a horizontal direction for connecting said organic light-emitting layers with the same horizontal position.

8. The method of claim 7, wherein said first electrode lines are made of indium tin oxide film and said second electrode lines are made of metal thin film.

9. The method of claim 7, wherein said grooves and said cavity matrix are formed using excimer laser.

10. The method of claim 7, wherein the step of forming a first electrode lines in said grooves comprises:
depositing an indium tin oxide thin film on said substrate, whereby said grooves are filled by said indium tin oxide thin film; and
removing extra part of said indium tin oxide thin film which is on said substrate surface and beyond the top of said grooves with chemical mechanical polishing.

11. The method of claim 7, wherein said organic light-emitting layer is form in every said cavity by inkjet printing.

12. The method of claim 7, wherein the step of filling an organic light-emitting layer in the cavities of said cavity matrix to form an organic light-emitting matrix comprises;
forming an organic light-emitting layer on said substrate using thermal evaporation, whereby said cavities are filled with said organic light-emitting layer; and
removing extra part of said organic light-emitting layer which is on said substrate surface and beyond the top of said cavities using chemical mechanical polishing.

13. An OLED display panel, comprising:
a substrate, on which a plurality of grooves are formed, said grooves are parallel to a vertical direction;
a plurality of electrode lines filled in said grooves;
a cavity matrix on said first electrode line, each cavity of the cavity matrix is filled in an organic light-emitting layer; and
a plurality of second electrode lines on said substrate and said organic light-emitting layer, said second electrode lines are parallel to a horizontal direction for connecting said organic light-emitting layer with the same horizontal position.

14. The OLED display panel of claim 13, wherein said first electrode lines are made of indium tin oxide film and said second electrode lines are made of metal thin film.

15. The OLED display panel of claim 13, wherein said organic light-emitting layer comprises a plurality of organic thin films.
